(19) United States
(12) Patent Application Publication
(10) Pub. No.: US 2026/0343753 A1
(43) Pub. Date: Oct. 29, 2026

(54) SHEET FOR MOLDING/UNDERFILL ENCAPSULATION AND METHOD FOR ENCAPSULATING PRINTED CIRCUIT BORAD USING SAME

(71) Applicant: NAGASE CHEMTEX CORPORATION, Osaka (JP)

(72) Inventors: Daisuke MORI, Hyogo (JP); Yuki SUGIURA, Hyogo (JP); Yasuhito FUJII, Hyogo (JP)

(21) Appl. No.: 19/099,226

(22) PCT Filed: Jul. 27, 2023
(86) PCT No.: PCT/JP2023/027537

§ 371 Date: Jan. 28, 2025

(30) Foreign Application Priority Data
Jul. 29, 2022 (JP) 2022-122192

(51) Int. Cl. H05K 3/28; C08G 59/22; C08G 59/24; C08G 59/26; C08G 59/62; C08J 5/18; C08L 63/04

(52) U.S. Cl. CPC H05K 3/285; C08G 59/226; C08G 59/245; C08G 59/26; C08G 59/621; C08J 5/18; C08L 63/04; C08J 2363/04; C08J 2433/04; C08J 2467/00; C08J 2471/02; C08J 2483/04; C08L 2203/162; C08L 2203/206

(57) ABSTRACT

Disclosed is a mold underfill sealing sheet for an electronic component mounting substrate that includes a plurality of electronic components and a substrate, and also includes a space between the electronic components and the substrate, the sheet including: a thermosetting resin composition sheet formed using a thermosetting resin composition, wherein the sheet has a viscosity increasing rate of less than 9, the viscosity increasing rate being a ratio (V90/V0) of a viscosity V90 obtained 90 seconds after a start of measurement performed at a measurement temperature of 125 °C for a measurement time of 150 seconds relative to a viscosity V0 obtained 0 seconds after the start of measurement.

### TECHNICAL FIELD

The present invention relates to a mold underfill sealing sheet and a method for sealing an electronic component mounting substrate using the same.

### BACKGROUND ART

For sealing electronic components that connected using a flip-chip connection method, it is common to use a method in which underfilling is performed to fill a space between the electronic components and a substrate with a flowable liquid sealing material, and then overmolding is performed using a different liquid sealing material or a sealing film (see Patent Literatures 1 to 3).

On the other hand, in order to reduce the number of processing steps, a material for mold underfill sealing in which underfill sealing and overmold sealing can be performed simultaneously has been proposed (see Patent Literature 4).

### CITATION LIST

### Patent Literature

PTL 1: Japanese Laid-Open Patent Publication No. 2014-131016
PTL 2: Japanese Laid-Open Patent Publication No. 2014-229769
PTL 3: Japanese Laid-Open Patent Publication No. 2015-178635
PTL 4: Japanese Laid-Open Patent Publication No. 2015-71670

### SUMMARY OF INVENTION

### Technical Problem

In the mold underfill sealing in which underfill sealing and overmold sealing are performed together, there are cases where sealing material unfilled portions (voids) are formed in the space between the plurality of electronic components and the substrate, which makes it difficult to perform sufficient underfill sealing in a stable manner.

### Solution to Problem

An aspect of the present invention relates to a mold underfill sealing sheet for an electronic component mounting substrate that includes a plurality of electronic components and a substrate, and also includes a space between the electronic components and the substrate, the sheet including: a thermosetting resin composition sheet formed using a thermosetting resin composition, wherein the sheet has a viscosity increasing rate of less than 9, the viscosity increasing rate being a ratio (V90/V0) of a viscosity V90 obtained 90 seconds after a start of measurement performed at a measurement temperature of 125 °C for a measurement time of 150 seconds relative to a viscosity V0 obtained 0 seconds after the start of measurement.

Another aspect of the present invention relates to a method for sealing an electronic component mounting substrate including the steps of: (a) preparing the electronic component mounting substrate that includes a plurality of electronic components and a substrate, and also includes a space between the electronic components and the substrate; (b) placing the above-described sheet on the electronic component mounting substrate so as to be in contact with the electronic components; and (c) heat molding the placed sheet to fill the space between the electronic components and the substrate with a melted material of the sheet and curing the melted material, wherein the heat molding is performed at a heating temperature of 110 °C or more and 175 °C or less.

### Advantageous Effects of Invention

According to the aspects of the present invention described above, when mold underfill sealing an electronic component mounting substrate that includes a space between electronic components and a substrate, sealing material unfilled portions (voids) are unlikely to be formed in the space between the electronic components and the substrate, and thus sufficient underfill sealing can be performed in a stable manner.

Novel features of the present invention are set forth in the appended claims. However, the present invention will be well understood from the following detailed description of the present invention with reference to the drawings, in terms of both the configuration and the content together with other objects and features of the present invention.

### BRIEF DESCRIPTION OF DRAWINGS

FIG. 1 is a conceptual diagram showing an example of an electronic component mounting substrate.

FIG. 2 is a diagram showing, as an example, a center C of a substrate, a frame line F that surrounds all of a plurality of electronic components while minimizing a surrounded area, an arbitrarily selected point P on the frame line, an outer edge S of a thermosetting sheet, and an intersecting point Q of a straight line Lcp that passes through the point P and the center C with the outer edge S.

FIG. 3 is a process diagram showing a method for sealing an electronic component mounting substrate.

### DESCRIPTION OF EMBODIMENTS

Hereinafter, an embodiment of the present disclosure will be described by way of examples. However, the present disclosure is not limited to the examples given below. In the following description, specific numerical values and materials may be listed as examples. However, other numerical values and materials may also be used as long as the advantageous effects of the present disclosure can be obtained. In the specification of the present application, the expression “a range of a numerical value A to a numerical value B” means that the range includes the numerical value A and the numerical value B, and can also be interpreted as “a numerical value A or more and a numerical value B or less”. In the following description, lower and upper limits of numerical values of specific physical properties, conditions, and the like will be shown. The lower limits and the upper limits shown below can be combined in any way as long as the lower limits are not greater than or equal to the upper limits. When a plurality of materials are listed, only one material may be selected from among the plurality of materials, or a combination of two or more may be selected from among the plurality of materials.

Also, the present disclosure encompasses a combination of features recited in any two or more claims arbitrarily selected from among the plurality of claims that are set forth in the appended claims. In other words, unless a technical contradiction arises, it is possible to combine features recited in any two or more claims arbitrarily selected from among the plurality of claims that are set forth in the appended claims.

In the following description, the terms “to contain” and “to include” are expressions that encompass “to contain (or include)”, “to substantially consist of” and “to be composed of”.

In the present disclosure, the term “thermosetting resin” may also be referred to as “sealing material” irrespective of before or after curing.

A thermosetting resin composition sheet (mold underfill sealing sheet) according to an embodiment of the present invention is a sealing material used for mold underfill sealing in which underfill sealing and overmold sealing are performed together. The object to be sealed is an electronic component mounting substrate that includes a plurality of electronic components and a substrate, and also includes a space between the electronic components and the substrate. In the mold underfill sealing, sealing of an electrode portion that connects the electronic components to the substrate (or in other words, underfill sealing) and sealing of all of the electronic components including the outer surfaces of the electronic components (or in other words, overmold sealing) are performed together at once.

The mold underfill sealing sheet (hereinafter, also referred to as “MUFS sheet”) is a sheet formed using an uncured or semi-cured (B-staged) thermosetting resin composition. As used herein, the term “semi-cured (B-staged) thermosetting resin composition” refers to a thermosetting resin composition that is solid at room temperature, but when heated to a predetermined temperature or more, turns to be flowable for a while, and then gradually loses the flowability as the curing reaction proceeds.

### <Viscosity Increasing Rate>

By controlling the viscosity increasing rate of the sheet to be less than 9, ease of filling the space (hereinafter, also referred to as “space S”) between the electronic components and the substrate with the sealing material (hereinafter, also referred to as “MUF property”) is significantly improved.

As used herein, the term “viscosity increasing rate” refers to a viscosity increasing rate measured under a measurement condition (hereinafter, referred to as “measurement condition (A)”) in which the measurement temperature is set to 125 °C and the measurement time is set to 150 seconds. The viscosity increasing rate is a ratio (V90/V0) of a viscosity V90 obtained 90 seconds after a start of viscosity measurement to a viscosity V0 obtained 0 seconds after the start of viscosity measurement. An example of a specific measurement method performed using the measurement condition (A) will be described below.

As an apparatus for measuring the viscosity increasing rate, for example, MCR 102 (available from Anton-Paar) is used. The measurement apparatus includes an upper plate and a lower plate for measurement that are attached to the measurement apparatus.

First, the lower plate is heated to 125 °C, and the temperature is stabilized.

Next, a test piece with a diameter ø of 25 mm is placed on a surface of the lower plate that has been heated to 125 °C. The test piece thereby begins to be heated to 125 °C. The test piece is prepared by being cut out from the MUFS sheet.

Within 30 seconds after placing the test piece on the lower plate, the apparatus is set to form a gap of 0.25 mm between the upper plate and the lower plate. When forming the gap, an excess portion of the test piece is removed.

After 30 seconds after placing the test piece on the lower plate, measurement is started. Then, the viscosity (V0) of the sealing material obtained 0 seconds after the start of measurement and the viscosity (V90) of the sealing material obtained 90 seconds after the start of measurement are measured, and the ratio (V90/V0) is calculated as the viscosity increasing rate.

All parameters for the measurement condition (A) are shown below.
Measurement temperature: 125 °C.
Measurement time: 0 to 150 seconds
Test piece size: circular shape with a diameter ø of 25 mm
Shear rate: 20 (1/s)
Thickness of thermosetting resin composition (sealing material): 0.25 mm
Viscosity increasing rate: viscosity obtained 90 seconds after start of measurement/viscosity obtained 0 seconds after start of measurement

In order to further improve the MUF property, the viscosity increasing rate may be set to 8.2 or less, 6.0 or less, or 3.0 or less. In the mold underfill sealing, it takes time for the space S, out of the space to be sealed, to be filled with the sealing material, and thus the sealing material is required to have a sufficient flowability during a period until the space S is fully filled. By controlling the viscosity increasing rate to be within the above-described range, it is possible to cause the sealing material to keep sufficient flowability during the period until the space S is fully filled with the sealing material.

In the above-described measurement, the sealing material has a viscosity at 125 °C of desirably 1000 Pa's or less, and more desirably 100 Pa's or less. When the sealing material has a low viscosity as described above, the MUF property is more significantly improved. The viscosity at 125 °C can be measured simultaneously with the measurement of the viscosity increasing rate. Here, a viscosity (V20) of the sealing material obtained 20 seconds after the start of measurement described above is measured.

### <Tan δ

The mold underfill sealing sheet has a maximum value of tan δ (loss tangent) of desirably less than 6, and may have a maximum value of tan δ of less than 3, 2.9 or less, 2.7 or less, or 2.5 or less. The maximum value of tan δ is measured under a measurement condition (hereinafter, referred to as “measurement condition (B)”) in which the measurement temperature is set to 125 °C and the measurement time is set to 0 to 70 seconds. When the maximum value of tan δ measured under the measurement condition (B) is within the above-described range, an amount of warpage of the electronic component mounting substrate that has undergone mold underfill sealing is significantly reduced.

For example, when the MUFS sheet is placed on a silicon wafer with a diameter ø of 12 inches and a thickness of 775 μm, and then heat molded under the following condition, the amount of warpage after curing can be reduced to 12 mm or less.

### <Condition>

Molding pressure: 5 MPa
Molding temperature: 125 °C.
Molding time: 10 minutes
Lowest vacuum degree: 200 Pa
Post mold curing (post-curing): 150 °C/3 h or 180 °C/1.5 h

When the maximum value of tan δ is within the above-described range, it is considered that the residual stress that remains in the cured sealing material (in particular, the overmold portion) is likely to be reduced, and thus the amount of warpage is reduced. An example of a specific measurement method performed using the measurement condition (B) will be described below.

As an apparatus for measuring tan δ, for example, ARES-LS2 (available from TA Instruments) is used.

A test piece with a diameter ø of 25 mm is set in the measurement apparatus.

The test piece is prepared by being cut out from the MUFS sheet.

Next, tan δ is measured at a frequency of, for example, 1 Hz.

All parameters for the measurement condition (B) are shown below.
Measurement temperature: 125 °C.
Measurement time: 0 to 70 seconds
Test piece size: circular shape with a diameter ø of 25 mm
Thickness of thermosetting resin composition (sealing material): 0.25 mm

From the viewpoint of enhancing the ease of filling the space (space S) between the electronic components and the substrate with the sealing material (MUF property), tan δ measured under the measurement condition (B) may be 0.2 or more, or 0.3 or more, and desirably, for example, 0.8 or more and less than 3.

The method for controlling tan δ measured under the measurement condition (B) to be within the above-described range is not particularly limited, and, for example, the following methods can be used: increasing filler content; applying a surface treatment agent to filler surface, selecting a base resin and a curing agent; and the like.

### <Storage Modulus>

The cured MUFS sheet has a storage modulus of, for example, 3 GPa or more, and may have a storage modulus of 5 GPa or more, and, for example, 40 GPa or less, or 30 GPa or less.

The storage modulus of the cured MUFS sheet is measured in the following procedure. First, a measurement sample with a length of 50 mm, a width of 10 mm, and a thickness of 2 mm is prepared from the cured MUFS sheet. As the cured MUFS sheet, a cured MUFS sheet obtained by heating a MUFS sheet at 175 °C for one hour to cure. Next, the measurement sample is set in a bending measurement jig, and then bending storage modulus in a temperature range of −50 to 300 °C is measured at a frequency of 1 Hz and a heating rate of 2.5 °C/min using a viscoelasticity measurement apparatus (DMA6100 available from Hitachi High-Tech Science Corporation). Storage modulus at 25 °C is read from the measurement result. The storage modulus can be used as an indicator of rigidity of the sheet. The MUFS sheet whose storage modulus after curing is within the above-described range has excellent handling performance.

### <Structure of MUFS Sheet>

The MUFS sheet may be a single-layer structure sheet. As used herein, the term “single-layer structure sheet” refers to a sheet that is formed using a single thermosetting resin composition. In order to improve the handling performance, the MUFS sheet may be attached to a release sheet, or may be sandwiched between two release sheets.

Alternatively, the MUFS sheet may have a multilayer structure. As used herein, the term “multilayer structure” refers to a structure in which two or more layers formed using thermosetting resin compositions that have different formulation compositions are stacked. A multilayer structure sheet requires a more complex production process than a single-layer structure sheet. Accordingly, from the viewpoint of simplifying the production process, it is more desirable that the MUFS sheet is a single-layer structure sheet.

The thickness of the MUFS sheet is not particularly limited, and is, for example, 50 μm or more. The thickness of the MUFS sheet may be 100 μm or more, 200 μm or more, or 400 μm or more. The thickness of the MUFS sheet is, for example, 1000 μm or less, and may be 800 μm or less.

### <Method for Producing MUFS Sheet>

A single-layer structure MUFS sheet is formed by molding a thermosetting resin composition into a single sheet. As the molding method, for example, any of the following methods can be used: a calendar film forming method, a casting film forming method, an inflation extrusion method, a T-die extrusion method, a dry lamination method; and the like. The MUFS sheet may be formed on a release sheet, and the release sheet may be removed before use.

The release sheet is not particularly limited, and is made of, for example, a plastic film, paper, a non-woven fabric, a metal, or the like. As the plastic film, for example, a polyolefin-based film, a halogenated vinyl polymer-based film, an acrylic resin-based film, a rubber-based film, a cellulose-based film, a polyester-based film, a polycarbonate-based film, a polystyrene-based film, a polyphenylene sulfide-based film, or a cycloolefin polymer-based film may be used. It is also possible to use a release sheet that has undergone release processing using silicon or the like.

### <Thermosetting Resin Composition>

The thermosetting resin composition that constitutes the MUFS sheet contains, for example, a base resin, a curing agent, and a filler.

### (Filler)

The filler is a solid component that is dispersible in the thermosetting resin composition and does not melt during the sealing process. The solid component may be either an inorganic material or an organic material. The solid component may be in the form of particles, plates, or fibers. An inorganic powder may be contained in the thermosetting resin composition as the filler.

As the inorganic powder, fused silica, crystalline silica, a quartz glass powder, calcium carbonate, aluminum hydroxide, or the like can be used. Out of these, it is preferable to use silica, and it is more preferable to use fused silica.

The filler content in the thermosetting resin composition is not particularly limited, and may be, for example, 50 mass % or more, 60 mass % or more, or 70 mass % or more. From the viewpoint of ease of controlling tan δ measured under the measurement condition (A) to be less than 3, the filler content is desirably 70 mass % or more. The upper limit of the filler content in the thermosetting resin composition is not particularly limited, and is, for example, 90 mass % or less. The upper limit of the filler content may be 85 mass % or less.

The maximum particle size (Dmax) of the filler is desirably smaller than a minimum distance (W) between electronic components that are objects to be sealed (a distance between the closest outer edges of adjacent electronic components) and a height (H) of the space between the electronic components and the substrate, and can be selected as appropriate according to the minimum distance (W) and the height (H). The maximum particle size (Dmax) of the filler may be, for example, 35 μm or less, 25 μm or less, 20 μm or less, or 10 μm or less.

The average particle size (D50) of the filler may be selected as appropriate according to the minimum distance (W) and the height (H), and is, for example, 0.5 μm or more. The average particle size (D50) of the filler may be 1 μm or more, or 2 μm or more. The average particle size (D50) of the filler may be, for example, 20 μm or less, 10 μm or less, or 5 μm or less (for example, 3 μm or less). The average particle size (D50) of the filler is a median diameter in at 50% cumulative volume of a volume particle size distribution.

The average particle size (D50) and the maximum particle size (Dmax) of the filler can be measured based on a laser diffraction scattering method using a laser diffraction particle size distribution measurement apparatus.

### (Base Resin)

The base resin is not particularly limited, and it is preferable to use an epoxy resin because it is superior in terms of heat resistance and cost.

The epoxy resin is not particularly limited, and any of the following epoxy resins can be used: a biphenyl-type epoxy resin, a bisphenol A-type epoxy resin, a bisphenol F-type epoxy resin, a bisphenol AD-type epoxy resin, a naphthalene-type epoxy resin, a glycidylamine-type epoxy resin, a phenol novolak-type epoxy resin, a phenolphthalein-type epoxy resin, a polyglycol-modified epoxy resin, a polyolefin-modified bisphenol A-type epoxy resin, an alicyclic epoxy resin, a dicyclopentadiene-type epoxy resin, a polyether-type epoxy resin, a silicon-modified epoxy resin, and the like. These epoxy resins may be used alone or in a combination of two or more. For example, when a bisphenol A-type epoxy resin is used as the epoxy resin, the bisphenol A-type epoxy resin content in the base resin is, for example, 50 mass % or more and 90 mass % or less, and may be 60 mass % or more and 90 mass % or less. For example, when a phenol novolak-type epoxy resin is used as the epoxy resin, the phenol novolak-type epoxy resin content in the base resin is, for example, 50 mass % or more and 90 mass % or less, and may be 60 mass % or more and 90 mass % or less.

In particular, from the viewpoint of improving the glass transition temperature, it is desirable that the base resin contains a solid epoxy resin that has a melting point of 50 °C or more.

From the viewpoint of ease of suppressing warpage of the electronic component mounting substrate after sealing, it is desirable that the base resin contains, as a portion of the base resin, at least one selected from the group consisting of an epoxy resin having an alkylene chain, an epoxy resin having a polyoxyalkylene chain, and a phenolphthalein-type epoxy resin. A phenolphthalein-type epoxy resin, an epoxy resin having an alkylene chain, and/or an epoxy resin having a polyoxyalkylene chain may be used in combination.

(Epoxy Resin having Alkylene Chain)

The content of the epoxy resin having an alkylene chain in the base resin is, for example, 5 mass % or more and 30 mass % or less, and may be 5 mass % or more and 20 mass % or less. The type of epoxy resin having an alkylene chain is not particularly limited as long as the epoxy resin has an alkylene chain. The epoxy resin having an alkylene chain may be an epoxy-modified polyol having 8 or more carbon atoms. Also, the epoxy resin having an alkylene chain may contain a bisphenol A-type epoxy resin as its basic backbone.

The epoxy resin having an alkylene chain may be any one of a glycidyl ether-type epoxy resin, a glycidyl ester-type epoxy resin, a glycidylamine-type epoxy resin, an alicyclic epoxy compound, and the like. From the viewpoint of ease of availability, a glycidyl ether having an alkylene chain (specifically, a glycol modified-type epoxy resin) or the like is used.

The number of carbon atoms contained in the alkylene chain is, for example, 1 or more, and may be 2 or more, or 3 or more. The number of carbon atoms contained in the polyolefin chain is preferably 10 or less, and may be 8 or less, or 6 or less.

Examples of the epoxy resin having an alkylene chain include a 1,6-hexanediol diglycidyl ether, a resorcinol diglycidyl ether, a propylene glycol diglycidyl ether, a cyclohexane dimethanol diglycidyl ether, and the like. Other examples include an epoxy-modified polybutadiene, an epoxy-modified polyisoprene, an epoxy-modified polyethylene, an epoxy-modified polypropylene, an epoxy-modified (meth)acrylic polymer, an epoxy-modified natural rubber, and the like.

(Epoxy Resin having Polyoxyalkylene Chain)

The content of the epoxy resin having a polyoxyalkylene chain in the base resin is, for example, 5 mass % or more and 30 mass % or less, and may be 5 mass % or more and 20 mass % or less. The epoxy resin having a polyoxyalkylene chain may contain a bisphenol A-type epoxy resin as its basic backbone.

The type of epoxy resin having a polyoxyalkylene chain is not particularly limited as long as the epoxy resin has a polyoxyalkylene chain. The epoxy resin having a polyoxyalkylene chain may be any one of a glycidyl ether-type epoxy resin, a glycidyl ester-type epoxy resin, a glycidylamine-type epoxy resin, an alicyclic epoxy compound, and the like. From the viewpoint of ease of availability, a glycidyl ether having a polyoxyalkylene chain (specifically, polyalkylene glycol glycidyl ether) or the like is used.

Examples of the glycidyl ether-type epoxy resin include a polyoxyethylene diglycidyl ether, a polyoxypropylene diglycidyl ether, a polyoxytrimethylene diglycidyl ether, a polyoxybutylene diglycidyl ether, a polyoxyhexamethylene diglycidyl ether, a polyoxyethylene·polyoxypropylene diglycidyl ether, and the like.

The number of carbon atoms contained in the polyoxyalkylene chain is, for example, 2 or more, preferably 3 or more, and more preferably 4 or more. The number of carbon atoms contained in the alkylene group is preferably 16 or less, and may be 10 or less, or 6 or less.

Specific examples of the alkylene group include ethylene, propylene, trimethylene, butylene (1,2-butylene, 1,3-butylene, 1,4-butylene (or tetramethylene) and the like), hexamethylene, octamethylene, decamethylene, and the like.

It is preferable that the repeat number n of oxyalkylene unit in the polyoxyalkylene chain is, for example, 3 or more, and may be 4 or more, or 5 or more. The repeat number n of oxyalkylene unit is, for example, 70 or less, and may be 30 or less, or 10 or less.

### (Phenolphthalein-Type Epoxy Resin)

The content of the phenolphthalein-type epoxy resin in the base resin is, for example, 50 mass % or more and 90 mass % or less, and may be 60 mass % or more and 90 mass % or less.

The phenolphthalein-type epoxy resin is a difunctional epoxy resin that has a bulky phenolphthalein backbone in a molecule. The phenolphthalein-type epoxy resin may have, for example, a glycidyl ether group at each of para-positions of two phenyl groups that are not bonded to a nitrogen atom. A specific example is phenolphthalein diglycidyl ether (N phenyl phenolphthalein diglycidyl ether).

The thermosetting resin composition may contain at least one selected from the group consisting of a polyol having an alkylene chain, a polyol having a polyoxyalkylene chain, an epoxy resin having an alkylene chain, an epoxy resin having a polyoxyalkylene chain, and a phenolphthalein-type epoxy resin.

### (Polyol Having Alkylene Chain)

The content of the polyol having an alkylene chain in the thermosetting resin composition is, for example, 5 mass % or more and 30 mass % or less, and may be 5 mass % or more and 20 mass % or less. The type of polyol having an alkylene chain is not particularly limited as long as the polyol has an alkylene chain, and the polyol having an alkylene chain may be a polyol having 8 or more carbon atoms. Examples of the polyol having 8 or more carbon atoms include a 1,4-cyclohexane dimethanol, a 1,2-cyclohexane dimethanol, a 1,3-cyclohexane dimethanol, a 2-methyl-1,1-cyclohexane dimethanol, a tricyclo[5.2.1.0^{2,6}]decane dimethanol, a 1,9-nonanediol, a 2-methyl-1,8-octanediol, a 1,10-decanediol, a 1,12-dodecanediol, a dimerdiol, a hydrogenated dimerdiol, and the like. Other examples include an alcohol-modified polybutadiene, an alcohol-modified polyisoprene, an alcohol-modified polyethylene, an alcohol-modified polypropylene, an alcohol-modified (meth)acrylic polymer, an alcohol-modified natural rubber, and the like.

### (Polyol Having Polyoxyalkylene Chain)

The content of the polyol having a polyoxyalkylene chain in the thermosetting resin composition is, for example, 5 mass % or more and 30 mass % or less, and may be 5 mass % or more and 20 mass % or less. The type of polyol having a polyoxyalkylene chain is not particularly limited as long as the polyol has a polyoxyalkylene chain.

Examples of the polyol having a polyoxyalkylene chain that can be used include a polyoxyethylene polyol, a polyoxypropylene polyol, a polyoxytetramethylene polyol, a polyoxyethylene polyoxypropylene polyol, a polyoxyethylene polyoxytetramethylene polyol, a polyoxypropylene polyoxytetramethylene polyol, and the like. These polyoxyalkylene polyols may be used alone or in a combination of two or more. The polyoxyalkylene polyol may have, for example, 2 to 6 hydroxyl groups, or 2 to 4 hydroxyl groups.

Examples of a polyol that constitutes the polyol having a polyoxyalkylene chain include diethylene glycol, triethylene glycol, polyethylene glycol, dipropylene glycol, tripropylene glycol, polypropylene glycol, dibutylene glycol, tributylene glycol, polybutylene glycol, polytetramethylene glycol, diglycerin, triglycerin, polyglycerin, polyoxyalkylene glycol (those including one or more alkylene oxides such as ethylene oxide, propylene oxide, and butylene oxide as an oxyalkylene constituent unit), mixtures thereof, polyoxyethylene glycerin, polyoxypropylene glyceryl ether, polyoxybutylene glyceryl ether, polyoxyalkylene glyceryl ether (those including one or more alkylene oxides such as ethylene oxide, propylene oxide, and butylene oxide as an oxyalkylene constituent unit), and the like.

### (Curing Agent)

As the curing agent for curing the base resin, a phenol resin, an acid anhydride, an amine compound, or the like can be used. Out of these, from the viewpoint of ease of suppressing warpage of the electronic component mounting substrate after sealing, it is preferable to use a phenol resin.

The phenol resin is not particularly limited, and it is preferable to use a phenol novolak resin. The phenol novolak resin is obtained by condensation polymerizing a phenol or a naphthol (for example, phenol, cresol, naphthol, alkylphenol, bisphenol, terpene phenol, naphthol, or the like) with formaldehyde. More specific examples include a phenol novolak resin, a cresol novolak resin, an aralkyl phenol novolak resin, a biphenylphenol novolak resin, a terpene phenol novolak resin, an α-naphthol novolak resin, a β-naphthol novolak resin, and the like. Out of these, from the viewpoint of water resistance, it is preferable to use a naphthol novolak resin. These resins may be used alone or in a combination of two or more.

Out of these, from the viewpoint of increasing the glass transition temperature, it is desirable that the curing agent contains a solid phenol novolak resin with a melting point of 60 °C or more.

The amount of the curing agent is controlled as appropriate to be within a range of, for example, 30 parts by mass or more and 80 parts by mass or less relative to 100 parts by mass of the base resin, and may be controlled to be within a range of 45 parts by mass or more and 60 parts by mass or less.

### (Curing Accelerator)

The thermosetting resin composition may contain a curing accelerator. The curing accelerator is not particularly limited, and examples include an imidazole-based accelerator, a phosphorus-based curing accelerator, a phosphonium salt-based curing accelerator, a bicyclic amidine, a derivative thereof, an organic metal complex, a urea compound of polyamine, and the like. The curing accelerator is preferably a latent curing accelerator. Examples of the latent curing accelerator include an imidazole-based accelerator, a phosphorus-based accelerator, and the like. Out of the latent curing accelerators, it is particularly preferable to use an encapsulated modified imidazole (a microcapsule-type curing accelerator).

The viscosity increasing rate may be controlled by selecting, for example, the type of curing accelerator and the amount of curing accelerator as appropriate. From the viewpoint of ease of controlling the viscosity increasing rate, it is desirable to use an imidazole-based accelerator.

The amount of the curing accelerator is controlled as appropriate to be within a range of, for example, 1 part by mass or more and 10 parts by mass or less relative to 100 parts by mass of the base resin, and may be controlled to be within a range of 2 parts by mass or more and 5 parts by mass or less.

### (Additive)

The thermosetting resin composition may further contain an additive. Examples of the additive include a silane coupling agent, carbon black, an antifoaming agent, a leveling agent, a pigment, a stress relieving agent, a thermoplastic resin, an ion scavenger, and the like. However, the additive is not limited thereto.

There are various types of silane coupling agents, and the properties (for example, viscosity at room temperature) of the resin composition may vary depending on the type of silane coupling agent used. Accordingly, a suitable silane coupling agent is selected as appropriate. The silane coupling agent may have a hydrolyzable group (an alkoxy group, a hydroxyl group, or the like) and may also have an alkyl group, an aliphatic or aromatic amino group (a phenylamino group or the like), an acrylic group, a methacrylic group, or the like.

The thermoplastic resin contributes to suppression of warpage of the electronic component mounting substrate after sealing and also contributes to gelation or solidification of the MUFS sheet.

The thermoplastic resin may have a weight average molecular weight (Mw) of, for example, 300,000 or less, 200,000 or less, or 100,000 or less. The weight average molecular weight Mw may be, for example, 5,000 or more. When the weight average molecular weight Mw of the thermoplastic resin is within this range, the thermoplastic resin is highly dispersible, and the elasticity of the cured material is likely to be reduced. Accordingly, the effect of suppressing warpage can be further enhanced.

In the specification of the present application, the weight average molecular weight Mw is a polystyrene equivalent weight average molecular weight determined based on gel permeation chromatography (GPC).

The thermoplastic resin may have a reactive functional group. Examples of the reactive functional group include an epoxy group, a carboxy group, a hydroxy group, an amino group (including an imino group), an amide group, a nitrile group, a group having a polymerizable carbon-carbon unsaturated bond (for example, a vinyl group, an allyl group, an acryloyl group, a methacryloyl group, and the like), and the like.

Examples of the thermoplastic resin include a diene-based thermoplastic resin (including an isoprene rubber, a butadiene rubber, a styrene butadiene rubber, a chloroprene rubber, and the like), an acrylic thermoplastic resin (including an acrylic rubber and the like), a nitrile-based thermoplastic resin (including a nitrile rubber and the like), a urethane-based thermoplastic resin (including a urethane rubber and the like), a silicone-based thermoplastic resin (including a silicone rubber, an epoxy-modified silicone, and the like), a polyester-based thermoplastic resin (including a crystalline polyester, an amorphous polyester, a polyester elastomer, and the like), a polyamide-based thermoplastic resin (including a polyether ester amide, a polyamide elastomer, and the like), a butyl rubber, an ethylene propylene rubber, and the like. These may be used alone or a combination of two or more.

From the viewpoint of easily controlling the molecular weight and the molecular weight distribution, easily introducing the reactive functional group, and easily dispersing in the thermosetting resin composition, an acrylic thermoplastic resin may be used. The acrylic thermoplastic resin contains a (meth)acrylate unit. The (meth)acrylate unit may be, for example, an alkyl (meth)acrylate unit or the like. The alkyl (meth)acrylate unit is, for example, a C₁₋₆ alkyl (meth)acrylate unit (an ethyl (meth)acrylate unit, a propyl (meth)acrylate unit, a butyl (meth)acrylate unit, and the like), and may be a C₁₋₄ alkyl (meth)acrylate unit. In the specification of the present application, acrylate and methacrylate are collectively referred to as “(meth)acrylate”.

The amount of the thermoplastic resin is, for example, 5 parts by mass or more and 30 parts by mass or less relative to 100 parts by mass of the base resin, and may be 5 parts by mass or more and 20 parts by mass or less.

### <Method for Sealing Electronic Component Mounting Substrate>

Hereinafter, an example of a method for sealing an electronic component mounting substrate according to an embodiment that uses the MUFS sheet will be described.

The method for sealing an electronic component mounting substrate according to the present embodiment includes the steps of: (a) preparing the electronic component mounting substrate that includes a plurality of electronic components and a substrate, and also includes a space between the electronic components and the substrate; (b) placing the MUFS sheet on the electronic component mounting substrate so as to be in contact with the electronic components; and (c) heat molding the placed MUFS sheet to fill the space between the electronic components and the substrate with a melted material of the sheet and curing the melted material. The heat molding is performed at a heating temperature of, for example, 110 °C or more and 175 °C or less.

According to the sealing method described above, it is possible to obtain an electronic component mounting substrate (hereinafter, also referred to as “sealed body”) that includes a substrate, electric components mounted on the substrate, and a cured sealing material that seals the electronic components. Accordingly, the sealing method according to the present embodiment is also a method for producing an electronic component mounting substrate (sealed body). Specifically, it can be said that the method is “a method for producing a sealed body of an electronic component mounting substrate including: the electronic component mounting substrate that includes a plurality of electronic components and a substrate, and also includes a space between the electronic components and the substrate; and a cured material of a mold underfill sealing sheet that undermold seals the space and overmold seals the electronic components”. The electronic component mounting substrate may be a single sealed body in which only one side of the substrate is sealed with the sealing material or a double sealed body in which both sides of the substrate are sealed with the sealing material.

In the electronic component mounting substrate prepared in the step (a), the plurality of electronic components are connected to the substrate (specifically, an electrode provided on the substrate) using, for example, a flip-chip connection method. In the flip-chip connection method, each electronic component is mounted on the substrate with a plurality of protruding terminals (also referred to as “bumps”) that are arranged in an array. The plurality of bumps are provided on a surface of the electronic component that faces the substrate. The bumps constitute a portion of the electronic component. The space between the electronic component and the substrate is generally occupied by a gap between the plurality of bumps.

The MUFS sheet used in the step (b) has the property of melting upon heating and thereafter curing. The MUFS sheet may be B-staged.

In the step (c), the MUFS sheet is heat molded using a mold. The mold presses the MUFS sheet placed on the electronic component mounting substrate against the substrate so as to cover the plurality of electronic components. The mold is heated at an arbitrary timing. Due to heating, the MUFS sheet melts, and the melted material flows into the space between the electronic components and the substrate to fill the space therebetween while covering the surfaces of the electronic components, and thereafter cures. That is, underfill sealing and overmold sealing that seals all of the electronic components are performed together at once. As used herein, the term “overmold sealing” means to seal at least a surface of an electronic component with a sealing material. The pressing surface of the mold may be covered with a release film.

In the above-described sealing method, the size and the shape of the MUFS sheet as viewed in a plan view may be designed according to a frame line (hereinafter, also referred to as “frame line F”) that surrounds all of the plurality of electronic components while minimizing the surrounded area. The size of the MUFS sheet as viewed in a plan view may be larger than the size of the substrate. However, from the viewpoint of cost and simplifying the sealing process, it is desirable that the size of the MUFS sheet is the same as or smaller than the size of the substrate.

Specifically, a distance between an arbitrarily selected point P on the frame line F and a center of the substrate (hereinafter, also referred to as “center C”) is represented by Lp. Also, an intersecting point of a straight line (hereinafter, also referred to as “straight line Lcp”) that passes through the point P and the center C with an outer edge of the MUFS sheet (hereinafter, also referred to as “outer edge S”) is defined as point Q. At this time, a distance (hereinafter, also referred to as “distance Lq”) between the point Q and the center C may be limited to 0.9 Lp or more.

The distance Lq may be set to 0.91 Lp or more, 0.93 Lp or more, or 0.96 Lp or more. Here, at 70% or more or 90% or more of the length of trajectory of the frame line F, the distance Lp and the distance Lq may satisfy the above-described relationship. It is desirable that, at 98% to 100% of the length of trajectory of the frame line F, the distance Lp and the distance Lq may satisfy the above-described relationship.

By taking the tolerance of the MUFS sheet, the tolerance of the substrate, and the tolerance of the mold into consideration, the distance Lq may be set to 1.0 Lp or more. Also, the substrate may be completely covered with the thermosetting sheet as viewed from above.

When the MUFS sheet has a circular shape, a radius R of the MUFS sheet corresponds to the distance Lq. At this time, the distance Lq (radius R) and a maximum value MLp of the distance Lp may satisfy the above-described relationship such as Lq≥0.9 MLp. MLp that is the maximum value of the distance Lp corresponds to the distance Lp when the point P is located, out of all of the electronic components on the substrate, at a position farthest away from the center of the substrate.

That is, in the present embodiment, the MUFS sheet is placed on the substrate so as to completely cover the plurality of electronic components or cover most of the plurality of electronic components as viewed from above. Even when the outer edge S of the MUFS sheet is located inside of the frame line F (closer to the center C), there is only a negligible distance between the point P and the point Q. In this case, more amount of pressure energy applied to the MUFS sheet from the mold is used to fill the space between the electronic components and the substrate with the melted material of the thermosetting sheet. Accordingly, the space between the electronic components and the substrate is more easily filled with the melted material (sealing material unfilled portions are unlikely to be formed), and thus sufficient underfill sealing can be performed in a stable manner. This advantageous effect becomes pronounced when, for example, a plurality of electronic components mounted on a large-area substrate are sealed together at once using a packaging technique such as panel level packaging (PLP) or wafer level packaging (WLP).

In the step (c), the pressure applied to MUFS sheet (or the melted material of the MUFS sheet) from the pressing surface of the mold may be, for example, 0.5 MPa or more and 15 MPa or less, or 2 MPa or more and 12 MPa or less. By setting the pressure within the above-described range, it is possible to facilitate entering of the melted material into the small space.

The upper limit for the distance Lq between the point Q and the center C is not particularly limited from the viewpoint of performing sufficient underfill sealing in a stable manner. However, taking the production cost and good handling performance of the MUFS sheet into consideration, the distance Lq may be, for example, 1.45 Lp or less, 1.2 Lp or less, 1.1 Lp or less, or 1.05 Lp or less.

The MUFS sheet may be heat molded under a reduced pressure atmosphere. In this case, a more favorable underfill portion can be formed. The reduced pressure atmosphere may be a pressure atmosphere lower than the atmospheric pressure, and is preferably a pressure atmosphere at, for example, 10000 Pa (pascal) or less, or in other words, 100 hectopascal (hPa) or less, 5000 Pa (pascal) or less, desirably less than 500 Pa (5 hPa), and more desirably less than 200 Pa (2 hPa).

In the sealed body obtained through the step (c), the cured sealing material includes an underfill portion that fills the space between the substrate and the electronic components and an overmold portion that seals the surfaces of the electronic components that do not face the substrate. The underfill portion and the overmold portion are continuous in structure. The boundary between the underfill portion and the overmold portion cannot be observed even with a microscope or the like, and there is no substantial difference in morphology (the state of structure) between the underfill portion and the overmold portion.

The type of substrate is not particularly limited, and encompasses, for example, a wafer, a panel, a glass substrate, a resin substrate, a printed wiring board, and the like. As the wafer, a silicon wafer, a sapphire wafer, a compound semiconductor wafer, or the like can be used. As the panel, a plate-like member used in a liquid crystal panel, an organic (or inorganic) LED panel, or the like can be used. As the resin substrate, a bismaleimide triazine substrate, a polyimide substrate, a fluorine resin substrate, or the like can be used. The substrate may be an assembly of electronic components. The assembly of electronic components may be, for example, an assembly of semiconductor chips before singulating into a plurality of pieces.

The electronic components may be active elements or passive elements. The electronic components may be semiconductor elements or other elements. The electronic components may be a semiconductor package such as a BGA (ball grid array) or a CSP (chip size package). Specific examples of the electronic components include a RFIC (radio frequency identifier), a chip multilayer LC filter, a dielectric filter, a multilayer ceramic capacitor (MLCC), and the like.

It is desirable that the outer shape of the substrate and the outer shape of the MUFS sheet generally match each other. The outer shape of the substrate and the outer shape of the MUFS sheet may be similar in shape. For example, when the substrate has a circular outer shape, the MUFS sheet may also have a circular outer shape. When the substrate has a rectangular outer shape, the MUFS sheet may also have a rectangular outer shape. When the substrate has a generally circular outer shape such as an orientation flat wafer, the MUFS sheet may also have a circular outer shape. Also, 70% or more of the length of the trajectory of the outer edge S of the MUFS sheet may satisfy the relationship of similarity with the outer shape of the substrate.

The electronic component size is not particularly limited, and the area of the surface of each electronic component that faces the substrate may be, for example, 1 mm² or more, or 3 mm² or more. The area of the surface of each electronic component that faces the substrate may be, for example, 1600 mm² or less, or 2500 mm² or less. The electronic component size can be determined by performing size measurement on a plurality of arbitrarily selected electronic components (for example, ten electronic components) on the substrate, and averaging the obtained measurement values.

The electronic component height is not particularly limited, and may be, for example, 5 μm or more and 800 μm or less, or 10 μm or more and 600 μm or less. As used herein, the term “electronic component height” refers to, for example, a distance from a contact position of a bump to the substrate to a maximum height of the electronic component. That is, according to the present embodiment, favorable underfill sealing and favorable overmold sealing can be performed together at once even when a substrate on which a plurality of micro electronic components with a height of about 5 μm are mounted is used.

The distance between electronic components is not particularly limited, and may be, for example, 5 μm or more and 2000 μm or less, or 10 μm or more and 1000 μm or less. A minimum distance (W) between electronic components is a distance (or in other words, gap spacing) between the closest outer edges of adjacent electronic components. That is, according to the present embodiment, favorable underfill sealing and favorable overmold sealing can be performed together at once even when a substrate in which electronic components are highly densely mounted with a gap spacing of about 5 μm is used. The minimum distance (W) between electronic components can be determined by performing distance measurement on a plurality of pairs of electronic components (for example, ten pairs) arbitrarily selected on the substrate, and averaging the obtained measurement values.

The height (H) of the space between the electronic components and the substrate may be, for example, 2 μm or more, 5 μm or more and 100 μm or less, or 10 μm or more and 80 μm or less. That is, according to the present embodiment, favorable underfill sealing and favorable overmold sealing can be performed together at once even when a substrate that includes small bumps and has a space height of about 2 to 5 μm is used. The height of the space between the electronic components and the substrate may be, for example, 40 μm or less, or 15 μm or less. As used herein, the term “the height of the space between the electronic components and the substrate” refers to a minimum distance between the surface of each electronic component that faces the substrate and the substrate. The minimum distance can be determined by performing distance measurement on a plurality of arbitrarily selected electronic components (for example, ten electronic components) on the substrate, and averaging the obtained measurement values.

In the electronic component mounting substrate (sealed body), the cured sealing material may have a maximum thickness T of, for example, 1.2 mm or less, 1.0 mm or less, 0.8 mm or less, or 0.4 mm or less (or in other words, 400 μm or less). The present embodiment is effective even when forming, for example, a thin sealed body as described above in packaging applications such as PLP and WLP, as well as performing favorable underfill sealing and favorable overmold sealing together at once.

In the sealed body, the maximum thickness T of the cured sealing material is a maximum distance from the surface of the substrate to a surface of the cured sealing material opposite to the substrate. The maximum thickness T can be determined by performing thickness measurement on a plurality of points (for example, ten points) on the substrate, and averaging the obtained measurement values.

Hereinafter, the sealing method will be described more specifically with reference to the drawings.

### Step (a)

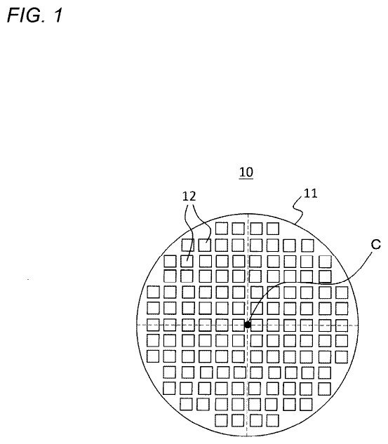

First, a substrate on which a plurality of electronic components are mounted is prepared. There is a space between the electronic components and the substrate. FIG. 1 is a conceptual diagram showing an example of an electronic component mounting substrate 10. A substrate 11 included in the electronic component mounting substrate 10 is a notch wafer that has a circular outer shape. A plurality of rectangular semiconductor chips are mounted on a surface of the substrate 11 as electronic components 12. Note that FIG. 1 is a conceptual diagram, and thus the size of the electronic components does not necessarily reflect the actual size.

### Step (b)

Next, a MUFS sheet 20 is placed on the substrate 11 so as to be in contact with the electronic components 12. Here, an arbitrarily selected point on a frame line F that surrounds all of the plurality of electronic components 12 while minimizing the surrounded area is defined as point P. A distance between the point P and a center C of the substrate is defined as distance Lp. An intersecting point of a straight line Lcp that passes through the point P and the center C of the substrate with an outer edge S of the MUFS sheet is defined as point Q. At this time, a distance Lq between the point Q and the center C of the substrate 11 satisfies 0.9 Lp or more.

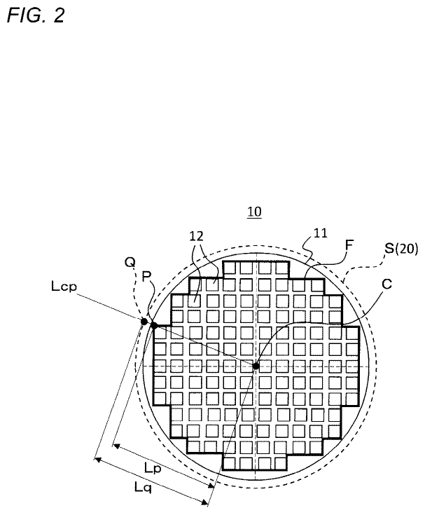

FIG. 2 is a diagram showing, as an example, the center C of the substrate 11, the frame line F that surrounds all of the plurality of electronic components 12 while minimizing the surrounded area, the arbitrarily selected point P on the frame line F, the outer edge S of the MUFS sheet 20, and the intersecting point Q of the straight line Lcp that passes through the point P and the center C with the outer edge S. The frame line F is indicated by a thick solid line. The outer edge S of the MUFS sheet 20 is indicated by a broken line. Here, an example is shown in which the distance Lq and the distance Lp satisfy Lq>Lp, but the distance Lq and the distance Lp may satisfy Lq≤Lp. Also, in this example, the MUFS sheet 20 is larger in size than the substrate 11 as viewed from above. However, the size of the MUFS sheet 20 may be less than or equal to the size of the substrate 11.

### Step (c)

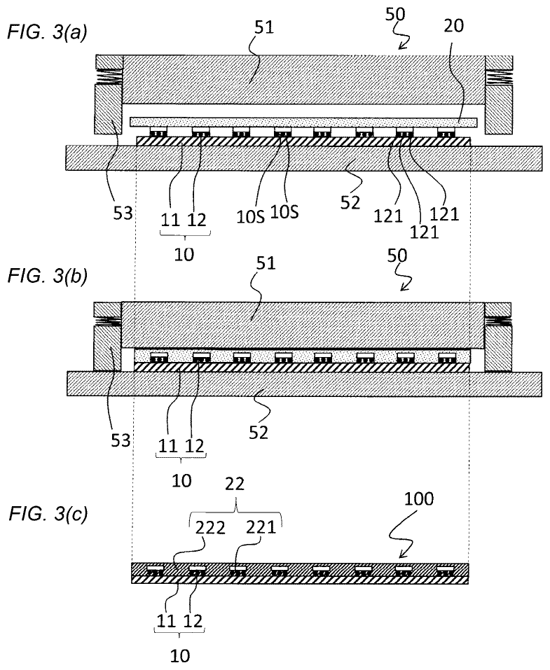

Next, the MUFS sheet 20 placed on the electronic component mounting substrate 10 is heat molded to fill the space between the electronic components 12 and the substrate 11 with a melted material of the MUFS sheet 20, and curing the melted material. FIG. 3 is a process diagram of a method for sealing the electronic component mounting substrate 10.

Specifically, as shown in FIG. 3(a), the electronic component mounting substrate 10 is set in a compression molding machine 50. The compression molding machine 50 includes an upper mold 51, a lower mold 52, and a flange portion 53 that is a portion of the upper mold and is fixed to a circumferential edge of the upper mold 51 via an elastic member such as a spring. The upper mold 51 has a flat pressing surface that presses the MUFS sheet 20. The pressing surface of the upper mold 51, a substrate placing surface of the lower mold 52, the flange portion 53, and the like may be covered with a release sheet. The plurality of electronic components 12 are connected to the surface of the substrate 11 via bumps 121. A space 10S is formed between surfaces of the electronic components 12 that face the substrate 11 and the substrate 11. The space 10S is mostly occupied by gaps between the bumps.

In the heat molding step, as shown in FIG. 3(b), the MUFS sheet 20 placed on the electronic component mounting substrate 10 is covered with the pressing surface of the upper mold, and then the MUFS sheet 20 is compressed while heating. At this time, a portion of a melted material of the MUFS sheet 20 enters the space 10S, and a curing reaction of the melted material proceeds.

At least one of the lower mold 52 and the upper mold 51 is heated to a temperature at which the curing reaction of the melted material of the MUFS sheet 20 proceeds. As the curing reaction of the melted material proceeds, an underfill portion 221 and an overmold portion 222 are simultaneously formed. As a result, a sealed body 100 in which the electronic component mounting substrate 10 is sealed with a cured sealing material 22 is obtained.

At least a portion of the step (c) may be performed under an atmospheric pressure or a reduced pressure atmosphere as already described. When the heat molding is performed under a reduced pressure atmosphere, air may be drawn through suction from an installation space where the compression molding machine 50 is installed.

The heating temperature is, for example, 80 to 200 °C, and may be 100 to 180 °C, and is desirably 110 to 140 °C. The heating time is, for example, 30 seconds to 30 minutes, and may be 2 minutes to 20 minutes.

The sealed body 100 may be further subjected to post mold curing (post-curing) after being taken out of the compression molding machine 50. The post mold curing may be performed at, for example, 100 to 180 °C for about 30 minutes to 3 hours.

### EXAMPLE

Hereinafter, the present invention will be described in further detail based on examples and comparative examples. However, the present invention is not limited to the examples given below.

### Examples 1 to 28 and Comparative Examples 1 to 6

### <Production of MUFS Sheet>

(1) In each of Examples 1 to 28 and Comparative Examples 1 to 6, materials were mixed at a composition ratio shown in tables given below, and then kneaded using a roll kneading machine to prepare a thermosetting resin composition. Note that all numerical values that indicate the composition ratio in the tables are expressed in part by mass.

(2) The obtained thermosetting resin composition was applied onto a release sheet and molded into a sheet at a temperature of 100 °C using a T-die extrusion method. In this way, a MUFS sheet with a thickness of 500 μm was produced. As the release sheet, a 50 μm-thick polyethylene terephthalate film that had undergone silicon release processing was used.

[Evaluation]

### <Measurement of Viscosity Increasing Rate>

Each of the MUFS sheets of Examples (Ex. 1 to Ex. 28) and Comparative Examples (Comp. 1 to Comp. 6) obtained above was subjected to viscosity increasing rate measurement using the method already described above.

### <MUF Property>

An evaluation sample of electronic component mounting substrate was produced by mounting five evaluation electronic components (TEGs) on a glass substrate with a circular outer shape and a diameter ø of 300 mm. The electronic components were arranged at a position corresponding to the center C of the substrate and four equiangular positions (at 0°, 90°, 180°, and) 270° around the center C such that the maximum distance between the point P on each electronic component and the center C of the substrate satisfied Lp=140 mm.

Each of the TEGs had a bump height corresponding to the height of the space between the electronic components and the substrate of 30 μm, a size of 25 mm×25 mm×300 μm (the electronic component height including bumps was 330 μm), a bump size of 20 μm, and a pitch between bump centers of 40 μm.

A MUFS sheet with a shape (circular shape) similar to the shape of the substrate with Lq=140 mm=1.0 Lp was placed on the sample so as to be in contact with the electronic components by aligning the center of the substrate with the center of the MUFS sheet, and then the MUFS sheet was heat molded under the following condition.
Molding pressure: 5 MPa
Molding temperature: 125 °C.
Molding time: 10 minutes
Lowest vacuum degree: 200 Pa
Post mold curing (post-curing): 175 °C/1 h

The state (filling property) of the underfill portion filling the space between the substrate and the electronic components was visually checked and evaluated. By directly observing from the underside of the glass substrate, the size of cured sealing material unfilled portions (voids) was rated based on the following criteria. As the void size, the largest one of those of the five evaluation electronic components (TEGs) was used. The results are shown in the tables given below.

A rating of A was given when the void size was 500 μm or less.

A rating of B was given when the void size was greater than 500 μm and 750 μm or less.

A rating of C was given when the void size was greater than 750 μm and 1000 μm or less.

A rating of F was given when the void size was greater than 1000 μm.

TABLE 1

| | | Dmax | D50 | Comp. | Comp. | Comp. | Comp. | Comp. | Comp. |
|---|---|---|---|---|---|---|---|---|---|
| | Type | (μm) | (μm) | 1 | 2 | 3 | 4 | 5 | 6 |
| Thermosetting | Biphenyl-type epoxy resin | | | 100 | 100 | | | | |
| resin | Bisphenol A-type epoxy resin | | | | | | | | |
| | Bisphenol F-type epoxy resin | | | | | | | | |
| | Naphthalene-type epoxy resin | | | | | | | | |
| | Glycidylamine-type epoxy resin | | | | | | | | |
| | Phenol novolak-type epoxy resin | | | | | | | | |
| | Phenolphthalein-type epoxy resin | | | | | 95 | 90 | 80 | 80 |
| | Glycol-modified epoxy resin | | | | | 5 | 10 | 20 | 20 |
| | Bisphenol A-modified epoxy resin | | | | | | | | |
| Curing agent | Solid phenol novolak A | | | 55 | 55 | 50 | 50 | 50 | 50 |
| | Solid phenol novolak B | | | | | | | | |
| Filler | Fused silica | 20 | 7.2 | | | | | | |
| | | 10 | 2.8 | | | 570 | 570 | 570 | 650 |
| | | 5 | 1.8 | 590 | 670 | | | | |
| | | 3 | 0.3 | | | | | | |
| | | 1 | 0.1 | | | | | | |
| Thermoplastic | Acrylic thermoplastic resin | | | | | | | | |
| resin | Ester-based thermoplastic resin | | | | | | | | |
| | Silicone-based thermoplastic resin | | | | | | | | |
| | Polyglycol-based thermoplastic resin | | | | | | | | |
| Carbon black | | | | 2 | 2 | 2 | 2 | 2 | 2 |
| Silane coupling agent A | | | | 2 | 2 | 2 | 2 | 2 | 2 |
| Ion scavenger | | | | 5 | 5 | 5 | 5 | 5 | 5 |
| Curing | Imidazole-based compound | 10 | 2 | | | | | | |
| accelerator | Triphenylphosphine-based compound | 10 | 1.5 | 3 | 3 | 3 | 3 | 3 | 3 |

| | | | | | | | |
|---|---|---|---|---|---|---|---|
| | Filler content [mass %] | 78 | 80 | 78 | 78 | 78 | 80 |
| Evaluation | Viscosity increasing rate | 9.4 | 9.7 | 9.3 | 9.2 | 9.0 | 9.2 |
| | MUF property | F | F | F | F | F | F |
| | Melt viscosity (Pa · s) | 33 | 42 | 825 | 652 | 438 | 521 |

TABLE 2

| | | Dmax | D50 | Ex. | Ex. | Ex. | Ex. | Ex. | Ex. | Ex. |
|---|---|---|---|---|---|---|---|---|---|---|
| | Type | (μm) | (μm) | 1 | 2 | 3 | 4 | 5 | 6 | 7 |
| Thermosetting | Biphenyl-type epoxy resin | | | 100 | | | | | | |
| resin | Bisphenol A-type epoxy resin | | | | | | | | | |
| | Bisphenol F-type epoxy resin | | | | | | | | | |
| | Naphthalene-type epoxy resin | | | | | | | | | |
| | Glycidylamine-type epoxy resin | | | | | | | | | |
| | Phenol novolak-type epoxy resin | | | | | | | | | |
| | Phenolphthalein-type epoxy resin | | | | 80 | 80 | 80 | 80 | 80 | 80 |
| | Glycol-modified epoxy resin | | | | 20 | 20 | 20 | 20 | 20 | 20 |
| | Bisphenol A-modified epoxy resin | | | | | | | | | |
| Curing agent | Solid phenol novolak A | | | 55 | 50 | 50 | 50 | 50 | 50 | 50 |
| | Solid phenol novolak B | | | | | | | | | |
| Filler | Fused silica | 20 | 7.2 | | | | | | | |
| | | 10 | 2.8 | | 650 | 650 | 650 | 650 | 650 | 800 |
| | | 5 | 1.8 | 670 | | | | | | |
| | | 3 | 0.3 | | | | | | | |
| | | 1 | 0.1 | | | | | | | |
| Thermoplastic | Acrylic thermoplastic resin | | | | | | | | | |
| resin | Ester-based thermoplastic resin | | | | | | | | | |
| | Silicone-based thermoplastic resin | | | | | | | | | |
| | Polyglycol-based thermoplastic resin | | | | | | | | | |
| Carbon black | | | | 2 | 2 | 2 | 2 | 2 | 2 | 2 |
| Silane coupling agent A | | | | 2 | 2 | 2 | 2 | 2 | 2 | 2 |
| Ion scavenger | | | | 5 | 5 | 5 | 5 | 5 | 5 | 5 |
| Curing | Imidazole-based compound | 10 | 2 | 2 | 2 | 4 | 6 | 8 | 10 | 2 |
| accelerator | Triphenylphosphine-based compound | 10 | 1.5 | | | | | | | |

| | | | | | | | | |
|---|---|---|---|---|---|---|---|---|
| | Filler content [mass %] | 80 | 80 | 80 | 80 | 80 | 80 | 83 |
| Evaluation | Viscosity increasing rate | 1.0 | 1.2 | 2.2 | 4.3 | 5.5 | 8.2 | 1.2 |
| | MUF property | A | A | A | B | B | B | B |
| | Melt viscosity (Pa · s) | 56 | 334 | 368 | 446 | 634 | 887 | 532 |

| | | Dmax | D50 | Ex. | Ex. | Ex. | Ex. | Ex. | Ex. |
|---|---|---|---|---|---|---|---|---|---|
| | Type | (μm) | (μm) | 8 | 9 | 10 | 11 | 12 | 13 |
| Thermosetting | Biphenyl-type epoxy resin | | | | 80 | | | | |
| resin | Bisphenol A-type epoxy resin | | | | | 80 | | | |
| | Bisphenol F-type epoxy resin | | | | | | 80 | | |
| | Naphthalene-type epoxy resin | | | | | | | | |
| | Glycidylamine-type epoxy resin | | | | | | | | |
| | Phenol novolak-type epoxy resin | | | | | | | | |
| | Phenolphthalein-type epoxy resin | | | 70 | | | | 70 | 70 |
| | Glycol-modified epoxy resin | | | 20 | 20 | 20 | 20 | 30 | 30 |
| | Bisphenol A-modified epoxy resin | | | 10 | | | | | |
| Curing agent | Solid phenol novolak A | | | 50 | 50 | 50 | 50 | 50 | 50 |
| | Solid phenol novolak B | | | | | | | | |
| Filler | Fused silica | 20 | 7.2 | | | | | | |
| | | 10 | 2.8 | 650 | 650 | 650 | 650 | 490 | 380 |
| | | 5 | 1.8 | | | | | | |
| | | 3 | 0.3 | | | | | | |
| | | 1 | 0.1 | | | | | | |
| Thermoplastic | Acrylic thermoplastic resin | | | | | | | | |
| resin | Ester-based thermoplastic resin | | | | | | | | |
| | Silicone-based thermoplastic resin | | | | | | | | |
| | Polyglycol-based thermoplastic resin | | | | | | | | |
| Carbon black | | | | 2 | 2 | 2 | 2 | 2 | 2 |
| Silane coupling agent A | | | | 2 | 2 | 2 | 2 | 2 | 2 |
| Ion scavenger | | | | 5 | 5 | 5 | 5 | 5 | 5 |
| Curing | Imidazole-based compound | 10 | 2 | 4 | 4 | 4 | 4 | 4 | 4 |
| accelerator | Triphenylphosphine-based compound | 10 | 1.5 | | | | | | |

| | | | | | | | |
|---|---|---|---|---|---|---|---|
| | Filler content [mass %] | 80 | 80 | 80 | 80 | 75 | 70 |
| Evaluation | Viscosity increasing rate | 2.0 | 1.2 | 1.5 | 1.7 | 2.3 | 2.5 |
| | MUF property | A | A | A | A | A | A |
| | Melt viscosity (Pa · s) | 253 | 21 | 17 | 14 | 102 | 28 |

TABLE 3

| | | Dmax | D50 | Ex. | Ex. | Ex. | Ex. | Ex. | Ex. | Ex. | Ex. |
|---|---|---|---|---|---|---|---|---|---|---|---|
| | Type | (μm) | (μm) | 14 | 15 | 16 | 17 | 18 | 19 | 20 | 21 |
| Thermosetting | Biphenyl-type epoxy resin | | | | | | | | | | |
| resin | Bisphenol A-type epoxy resin | | | | | | | | | | |
| | Bisphenol F-type epoxy resin | | | | | | | | | | |
| | Naphthalene-type epoxy resin | | | 80 | | | | | | | |
| | Glycidylamine-type epoxy resin | | | | 80 | | | | | | |
| | Phenol novolak-type epoxy resin | | | | | 80 | | | | | |
| | Phenolphthalein-type epoxy resin | | | | | | 80 | 80 | 80 | 80 | 80 |
| | Glycol-modified epoxy resin | | | 20 | 20 | 20 | 20 | 20 | 20 | 20 | 20 |
| | Bisphenol A-modified epoxy resin | | | | | | | | | | |
| Curing agent | Solid phenol novolak A | | | 50 | 50 | 50 | 50 | 50 | 50 | 50 | 50 |
| | Solid phenol novolak B | | | | | | | | | | |
| Filler | Fused silica | 20 | 7.2 | | | | 800 | | | | |
| | | 10 | 2.8 | 650 | 650 | 650 | | | | | 670 |
| | | 5 | 1.8 | | | | | 650 | | | |
| | | 3 | 0.3 | | | | | | 490 | | |
| | | 1 | 0.1 | | | | | | | 380 | |
| Thermoplastic | Acrylic thermoplastic resin | | | | | | | | | | 5 |
| resin | Ester-based thermoplastic resin | | | | | | | | | | |
| | Silicone-based thermoplastic resin | | | | | | | | | | |
| | Polyglycol-based thermoplastic resin | | | | | | | | | | |
| Carbon black | | | | 2 | 2 | 2 | 2 | 2 | 2 | 2 | 2 |
| Silane coupling agent A | | | | 2 | 2 | 2 | 2 | 2 | 2 | 2 | 2 |
| Ion scavenger | | | | 5 | 5 | 5 | 5 | 5 | 5 | 5 | 5 |
| Curing | Imidazole-based compound | 10 | 2 | 4 | 4 | 4 | 4 | 4 | 4 | 4 | 4 |
| accelerator | Triphenylphosphine-based compound | 10 | 1.5 | | | | | | | | |

| | | | | | | | | | |
|---|---|---|---|---|---|---|---|---|---|
| | Filler content [mass %] | 80 | 80 | 80 | 83 | 80 | 75 | 70 | 80 |
| Evaluation | Viscosity increasing rate | 1.9 | 3.0 | 2.2 | 2.3 | 2.0 | 2.2 | 2.4 | 2.3 |
| | MUF property | A | A | A | A | A | A | A | A |
| | Melt viscosity (Pa · s) | 18 | 32 | 283 | 352 | 938 | 543 | 527 | 425 |

| | | Dmax | D50 | Ex. | Ex. | Ex. | Ex. | Ex. | Ex. | Ex. |
|---|---|---|---|---|---|---|---|---|---|---|
| | Type | (μm) | (μm) | 22 | 23 | 24 | 25 | 26 | 27 | 28 |
| Thermosetting | Biphenyl-type epoxy resin | | | | | | | | | |
| resin | Bisphenol A-type epoxy resin | | | | | | | | | |
| | Bisphenol F-type epoxy resin | | | | | | | | | |
| | Naphthalene-type epoxy resin | | | | | | | | | |
| | Glycidylamine-type epoxy resin | | | | | | | | | |
| | Phenol novolak-type epoxy resin | | | | | | | | | |
| | Phenolphthalein-type epoxy resin | | | 80 | 80 | 80 | 80 | 95 | 95 | 95 |
| | Glycol-modified epoxy resin | | | 20 | 20 | 20 | 20 | 5 | 5 | 5 |
| | Bisphenol A-modified epoxy resin | | | | | | | | | |
| Curing agent | Solid phenol novolak A | | | 50 | 50 | 50 | 50 | 50 | 50 | 50 |
| | Solid phenol novolak B | | | | | | | | | |
| Filler | Fused silica | 20 | 7.2 | | | | | | | |
| | | 10 | 2.8 | 670 | 730 | 730 | 730 | 860 | 740 | 650 |
| | | 5 | 1.8 | | | | | | | |
| | | 3 | 0.3 | | | | | | | |
| | | 1 | 0.1 | | | | | | | |
| Thermoplastic | Acrylic thermoplastic resin | | | | | | | | | |
| resin | Ester-based thermoplastic resin | | | 5 | | | | | | |
| | Silicone-based thermoplastic resin | | | | 10 | 20 | | | | |
| | Polyglycol-based thermoplastic resin | | | | | | 20 | | | |
| Carbon black | | | | 2 | 2 | 2 | 2 | 2 | 2 | 2 |
| Silane coupling agent A | | | | 2 | 2 | 2 | 2 | 2 | 2 | 2 |
| Ion scavenger | | | | 5 | 5 | 5 | 5 | 5 | 5 | 5 |
| Curing | Imidazole-based compound | 10 | 2 | 4 | 4 | 4 | 4 | 4 | 4 | 4 |
| accelerator | Triphenylphosphine-based compound | 10 | 1.5 | | | | | | | |

| | | | | | | | | |
|---|---|---|---|---|---|---|---|---|
| | Filler content [mass %] | 80 | 80 | 80 | 80 | 84 | 82 | 80 |
| Evaluation | Viscosity increasing rate | 2.3 | 2.7 | 2.5 | 2.2 | 2.5 | 2.0 | 2.1 |
| | MUF property | A | A | A | A | C | C | C |
| | Melt viscosity (Pa · s) | 410 | 303 | 271 | 237 | 1489 | 1267 | 1050 |

It can be seen, from Tables 1 to 3, that when the viscosity increasing rate is 9 or less, the MUF property is significantly improved.

### <Measurement of Maximum Value of Tan δ>

Tan δ was measured for each of the MUFS sheets obtained above using the method already described above.

### <Amount of Warpage>

Each of the MUFS sheets obtained above was placed on a silicon wafer with a diameter ø of 12 inches and a thickness of 775 μm, and then heat molded under the following condition.
Molding pressure: 5 MPa
Molding temperature: 125 °C.
Molding time: 10 minutes
Lowest vacuum degree: 200 Pa
Post mold curing (post-curing): 150 °C/3 h or 180 °C/1.5 h

The stacked body of the silicon wafer and the sealing material after post-curing was cooled to room temperature, and the amount of warpage was rated based on the following criteria. Using a laser displacement meter, on a surface of the silicon wafer on which the sealing material was not provided, a height difference between two points including the wafer center portion and the wafer end portion was measured, and the measured values were averaged. The obtained average value was defined as the amount of warpage. The amount of warpage was rated based on the following criteria. The results are shown in the tables given below.

A rating of A was given when the amount of warpage was 12 mm or less.

A rating of B was given when the amount of warpage was greater than 12 mm.

TABLE 4

| | | Dmax | D50 | Comp. | Comp. | Comp. | Comp. | Comp. | Comp. |
|---|---|---|---|---|---|---|---|---|---|
| | Type | (μm) | (μm) | 1 | 2 | 3 | 4 | 5 | 6 |
| Thermosetting | Biphenyl-type epoxy resin | | | 100 | 100 | | | | |
| resin | Bisphenol A-type epoxy resin | | | | | | | | |
| | Bisphenol F-type epoxy resin | | | | | | | | |
| | Naphthalene-type epoxy resin | | | | | | | | |
| | Glycidylamine-type epoxy resin | | | | | | | | |
| | Phenol novolak-type epoxy resin | | | | | | | | |
| | Phenolphthalein-type epoxy resin | | | | | 95 | 90 | 80 | 80 |
| | Glycol-modified epoxy resin | | | | | 5 | 10 | 20 | 20 |
| | Bisphenol A-modified epoxy resin | | | | | | | | |
| Curing agent | Solid phenol novolak A | | | 55 | 55 | 50 | 50 | 50 | 50 |
| | Solid phenol novolak B | | | | | | | | |
| Filler | Fused silica | 20 | 7.2 | | | | | | |
| | | 10 | 2.8 | | | 570 | 570 | 570 | 650 |
| | | 5 | 1.8 | 590 | 670 | | | | |
| | | 3 | 0.3 | | | | | | |
| | | 1 | 0.1 | | | | | | |
| Thermoplastic | Acrylic thermoplastic resin | | | | | | | | |
| resin | Ester-based thermoplastic resin | | | | | | | | |
| | Silicone-based thermoplastic resin | | | | | | | | |
| | Polyglycol-based thermoplastic resin | | | | | | | | |
| Carbon black | | | | 2 | 2 | 2 | 2 | 2 | 2 |
| Silane coupling agent A | | | | 2 | 2 | 2 | 2 | 2 | 2 |
| Ion scavenger | | | | 5 | 5 | 5 | 5 | 5 | 5 |
| Curing | Imidazole-based compound | 10 | 2 | | | | | | |
| accelerator | Triphenylphosphine-based compound | 10 | 1.5 | 3 | 3 | 3 | 3 | 3 | 3 |

| | | | | | | | |
|---|---|---|---|---|---|---|---|
| | Filler content [mass %] | 78 | 80 | 78 | 78 | 78 | 80 |
| Evaluation | Maximum value of tanδ | 2.0 | 0.7 | 0.7 | 1.2 | 2.0 | 0.8 |
| | Amount of warpage | B | A | B | A | A | A |
| | Melt viscosity (Pa · s) | 33 | 42 | 825 | 652 | 438 | 521 |

TABLE 5

| | | Dmax | D50 | Ex. | Ex. | Ex. | Ex. | Ex. | Ex. | Ex. |
|---|---|---|---|---|---|---|---|---|---|---|
| | Type | (μm) | (μm) | 6 | 7 | 8 | 9 | 10 | 11 | 12 |
| Thermosetting | Biphenyl-type epoxy resin | | | 100 | | | | | | |
| resin | Bisphenol A-type epoxy resin | | | | | | | | | |
| | Bisphenol F-type epoxy resin | | | | | | | | | |
| | Naphthalene-type epoxy resin | | | | | | | | | |
| | Glycidylamine-type epoxy resin | | | | | | | | | |
| | Phenol novolak-type epoxy resin | | | | | | | | | |
| | Phenolphthalein-type epoxy resin | | | | 80 | 80 | 80 | 80 | 80 | 80 |
| | Glycol-modified epoxy resin | | | | 20 | 20 | 20 | 20 | 20 | 20 |
| | Bisphenol A-modified epoxy resin | | | | | | | | | |
| Curing agent | Solid phenol novolak A | | | 55 | 50 | 50 | 50 | 50 | 50 | 50 |
| | Solid phenol novolak B | | | | | | | | | |
| Filler | Fused silica | 20 | 7.2 | | | | | | | |
| | | 10 | 2.8 | | 650 | 650 | 650 | 650 | 650 | 800 |
| | | 5 | 1.8 | 670 | | | | | | |
| | | 3 | 0.3 | | | | | | | |
| | | 1 | 0.1 | | | | | | | |
| Thermoplastic | Acrylic thermoplastic resin | | | | | | | | | |
| resin | Ester-based thermoplastic resin | | | | | | | | | |
| | Silicone-based thermoplastic resin | | | | | | | | | |
| | Polyglycol-based thermoplastic resin | | | | | | | | | |
| Carbon black | | | | 2 | 2 | 2 | 2 | 2 | 2 | 2 |
| Silane coupling agent A | | | | 2 | 2 | 2 | 2 | 2 | 2 | 2 |
| Ion scavenger | | | | 5 | 5 | 5 | 5 | 5 | 5 | 5 |
| Curing | Imidazole-based compound | 10 | 2 | 2 | 2 | 4 | 6 | 8 | 10 | 2 |
| accelerator | Triphenylphosphine-based compound | 10 | 1.5 | | | | | | | |

| | | | | | | | | |
|---|---|---|---|---|---|---|---|---|
| | Filler content [mass %] | 80 | 80 | 80 | 80 | 80 | 80 | 83 |
| Evaluation | Maximum value of tanδ | 0.7 | 0.8 | 0.7 | 0.6 | 0.3 | 0.2 | 0.2 |
| | Amount of warpage | A | A | A | A | A | A | A |
| | Melt viscosity (Pa · s) | 56 | 334 | 368 | 446 | 634 | 887 | 532 |

| | | Dmax | D50 | Ex. | Ex. | Ex. | Ex. | Ex. | Ex. |
|---|---|---|---|---|---|---|---|---|---|
| | Type | (μm) | (μm) | 13 | 14 | 15 | 16 | 12 | 13 |
| Thermosetting | Biphenyl-type epoxy resin | | | | 80 | | | | |
| resin | Bisphenol A-type epoxy resin | | | | | 80 | | | |
| | Bisphenol F-type epoxy resin | | | | | | 80 | | |
| | Naphthalene-type epoxy resin | | | | | | | | |
| | Glycidylamine-type epoxy resin | | | | | | | | |
| | Phenol novolak-type epoxy resin | | | | | | | | |
| | Phenolphthalein-type epoxy resin | | | 70 | | | | 70 | 70 |
| | Glycol-modified epoxy resin | | | 20 | 20 | 20 | 20 | 30 | 30 |
| | Bisphenol A-modified epoxy resin | | | 10 | | | | | |
| Curing agent | Solid phenol novolak A | | | 50 | 50 | 50 | 50 | 50 | 50 |
| | Solid phenol novolak B | | | | | | | | |
| Filler | Fused silica | 20 | 7.2 | | | | | | |
| | | 10 | 2.8 | 650 | 650 | 650 | 650 | 490 | 380 |
| | | 5 | 1.8 | | | | | | |
| | | 3 | 0.3 | | | | | | |
| | | 1 | 0.1 | | | | | | |
| Thermoplastic | Acrylic thermoplastic resin | | | | | | | | |
| resin | Ester-based thermoplastic resin | | | | | | | | |
| | Silicone-based thermoplastic resin | | | | | | | | |
| | Polyglycol-based thermoplastic resin | | | | | | | | |
| Carbon black | | | | 2 | 2 | 2 | 2 | 2 | 2 |
| Silane coupling agent A | | | | 2 | 2 | 2 | 2 | 2 | 2 |
| Ion scavenger | | | | 5 | 5 | 5 | 5 | 5 | 5 |
| Curing | Imidazole-based compound | 10 | 2 | 4 | 4 | 4 | 4 | 4 | 4 |
| accelerator | Triphenylphosphine-based compound | 10 | 1.5 | | | | | | |

| | | | | | | | |
|---|---|---|---|---|---|---|---|
| | Filler content [mass %] | 80 | 80 | 80 | 80 | 75 | 70 |
| Evaluation | Maximum value of tanδ | 1.2 | 2.8 | 2.9 | 2.7 | 4.2 | 5.8 |
| | Amount of warpage | A | A | A | A | A | A |
| | Melt viscosity (Pa · s) | 253 | 21 | 17 | 14 | 102 | 28 |

TABLE 6

| | | Dmax | D50 | Ex. | Ex. | Ex. | Ex. | Ex. | Ex. | Ex. | Ex. |
|---|---|---|---|---|---|---|---|---|---|---|---|
| | Type | (μm) | (μm) | 14 | 15 | 16 | 17 | 18 | 19 | 20 | 21 |
| Thermosetting | Biphenyl-type epoxy resin | | | | | | | | | | |
| resin | Bisphenol A-type epoxy resin | | | | | | | | | | |
| | Bisphenol F-type epoxy resin | | | | | | | | | | |
| | Naphthalene-type epoxy resin | | | 80 | | | | | | | |
| | Glycidylamine-type epoxy resin | | | | 80 | | | | | | |
| | Phenol novolak-type epoxy resin | | | | | 80 | | | | | |
| | Phenolphthalein-type epoxy resin | | | | | | 80 | 80 | 80 | 80 | 80 |
| | Glycol-modified epoxy resin | | | 20 | 20 | 20 | 20 | 20 | 20 | 20 | 20 |
| | Bisphenol A-modified epoxy resin | | | | | | | | | | |
| Curing agent | Solid phenol novolak A | | | 50 | 50 | 50 | 50 | 50 | 50 | 50 | 50 |
| | Solid phenol novolak B | | | | | | | | | | |
| Filler | Fused silica | 20 | 7.2 | | | | 800 | | | | |
| | | 10 | 2.8 | 650 | 650 | 650 | | | | | 670 |
| | | 5 | 1.8 | | | | | 650 | | | |
| | | 3 | 0.3 | | | | | | 490 | | |
| | | 1 | 0.1 | | | | | | | 380 | |
| Thermoplastic | Acrylic thermoplastic resin | | | | | | | | | | 5 |
| resin | Ester-based thermoplastic resin | | | | | | | | | | |
| | Silicone-based thermoplastic resin | | | | | | | | | | |
| | Polyglycol-based thermoplastic resin | | | | | | | | | | |
| Carbon black | | | | 2 | 2 | 2 | 2 | 2 | 2 | 2 | 2 |
| Silane coupling agent A | | | | 2 | 2 | 2 | 2 | 2 | 2 | 2 | 2 |
| Ion scavenger | | | | 5 | 5 | 5 | 5 | 5 | 5 | 5 | 5 |
| Curing | Imidazole-based compound | 10 | 2 | 4 | 4 | 4 | 4 | 4 | 4 | 4 | 4 |
| accelerator | Triphenylphosphine-based compound | 10 | 1.5 | | | | | | | | |

| | | | | | | | | | |
|---|---|---|---|---|---|---|---|---|---|
| | Filler content [mass %] | 80 | 80 | 80 | 83 | 80 | 75 | 70 | 80 |
| Evaluation | Maximum value of tanδ | 2.5 | 2.2 | 1.6 | 0.8 | 1.2 | 0.9 | 0.9 | 0.9 |
| | Amount of warpage | A | A | A | A | A | A | A | A |
| | Melt viscosity (Pa · s) | 18 | 32 | 283 | 352 | 938 | 543 | 527 | 425 |

| | | Dmax | D50 | Ex. | Ex. | Ex. | Ex. | Ex. | Ex. | Ex. |
|---|---|---|---|---|---|---|---|---|---|---|
| | Type | (μm) | (μm) | 22 | 23 | 24 | 25 | 26 | 27 | 28 |
| Thermosetting | Biphenyl-type epoxy resin | | | | | | | | | |
| resin | Bisphenol A-type epoxy resin | | | | | | | | | |
| | Bisphenol F-type epoxy resin | | | | | | | | | |
| | Naphthalene-type epoxy resin | | | | | | | | | |
| | Glycidylamine-type epoxy resin | | | | | | | | | |
| | Phenol novolak-type epoxy resin | | | | | | | | | |
| | Phenolphthalein-type epoxy resin | | | 80 | 80 | 80 | 80 | 95 | 95 | 95 |
| | Glycol-modified epoxy resin | | | 20 | 20 | 20 | 20 | 5 | 5 | 5 |
| | Bisphenol A-modified epoxy resin | | | | | | | | | |
| Curing agent | Solid phenol novolak A | | | 50 | 50 | 50 | 50 | 50 | 50 | 50 |
| | Solid phenol novolak B | | | | | | | | | |
| Filler | Fused silica | 20 | 7.2 | | | | | | | |
| | | 10 | 2.8 | 670 | 730 | 730 | 730 | 860 | 740 | 650 |
| | | 5 | 1.8 | | | | | | | |
| | | 3 | 0.3 | | | | | | | |
| | | 1 | 0.1 | | | | | | | |
| Thermoplastic | Acrylic thermoplastic resin | | | | | | | | | |
| resin | Ester-based thermoplastic resin | | | 5 | | | | | | |
| | Silicone-based thermoplastic resin | | | | 10 | 20 | | | | |
| | Polyglycol-based thermoplastic resin | | | | | | 20 | | | |
| Carbon black | | | | 2 | 2 | 2 | 2 | 2 | 2 | 2 |
| Silane coupling agent A | | | | 2 | 2 | 2 | 2 | 2 | 2 | 2 |
| Ion scavenger | | | | 5 | 5 | 5 | 5 | 5 | 5 | 5 |
| Curing | Imidazole-based compound | 10 | 2 | 4 | 4 | 4 | 4 | 4 | 4 | 4 |
| accelerator | Triphenylphosphine-based compound | 10 | 1.5 | | | | | | | |

| | | | | | | | | |
|---|---|---|---|---|---|---|---|---|
| | Filler content [mass %] | 80 | 80 | 80 | 80 | 84 | 82 | 80 |
| Evaluation | Maximum value of tanδ | 0.8 | 0.9 | 1.2 | 1.4 | 2.5 | 2.0 | 2.1 |
| | Amount of warpage | A | A | A | A | A | A | A |
| | Melt viscosity (Pa · s) | 410 | 303 | 271 | 237 | 1489 | 1267 | 1050 |

It can be seen, from Tables 4 to 6, that when tan δ is less than 6, the amount of warpage is significantly reduced in MUF sealing.

The present invention has been described in terms of the presently preferred embodiments, but the disclosure should not be interpreted as limiting. Various alterations and modifications will no doubt become apparent to those skilled in the art to which the present invention pertains, after having read the disclosure. Accordingly, it is to be understood that the appended claims be interpreted as covering all alterations and modifications which fall within the true spirit and scope of the present invention.

### INDUSTRIAL APPLICABILITY

With the mold underfill sealing sheet according to the present invention, when an electronic component mounting substrate in which a space is formed between electronic components and the substrate is subjected to mold underfill sealing, it is possible to reduce warpage of the substrate. In addition, it is also possible to achieve a method for sealing an electronic component mounting substrate that has excellent MUF property. The present invention is applicable to sealing of, for example, large scale integrated circuits and integrated circuits used in IOT, autonomous driving, and the like.

### REFERENCE SIGNS LIST

10: electronic component mounting substrate
10S: space
11: substrate
12: electronic component
121: bump
20: MUFS sheet
22: cured sealing material
221: underfill portion
222: overmold portion
50: compression molding machine
51: upper mold
52: lower mold
53: flange portion
F: frame line
C: center of substrate
P: arbitrarily selected point on frame line
Lp: distance between point P and center C
Lcp: straight line that passes through point P and center C
S: outer edge of thermosetting sheet
Q: intersecting point of Lcp with outer edge S
Lq: distance between point Q and center C

1. A sheet comprising a thermosetting resin composition, the sheet being a mold underfill sealing sheet for an electronic component mounting substrate that includes a plurality of electronic components and a substrate, and also includes a space between the electronic components and the substrate,
wherein the sheet has a viscosity increasing rate of less than 9, the viscosity increasing rate being a ratio (V90/V0) of a viscosity V90 obtained 90 seconds after a start of measurement performed at a measurement temperature of 125 °C for a measurement time of 150 seconds relative to a viscosity V0 obtained 0 seconds after the start of measurement.

2. The sheet in accordance with claim 1,
wherein the sheet has a viscosity at 125 °C of 1000 Pa·s or less.

3. The sheet in accordance with claim 1,
wherein the sheet has a maximum value of tan δ (loss tangent) of 0.2 or more, the maximum value of tan δ being measured at a measurement temperature of 125 °C for a measurement time of 0 to 70 seconds.

4. The sheet in accordance with claim 3,
wherein the maximum value of tan δ of the sheet is less than 6.

5. The sheet in accordance with claim 1,
wherein the thermosetting resin composition contains a base resin, a curing agent, and a filler, and
the filler is contained at a content of 70 mass % or more.

6. The sheet in accordance with claim 5,
wherein the filler has a maximum particle size of 35 μm or less.

7. The sheet in accordance with claim 5,
wherein the filler has an average particle size of 20 μm or less.

8. The sheet in accordance with claim 1,
wherein the thermosetting resin composition contains at least one selected from the group consisting of a polyol having an alkylene chain, an epoxy resin having an alkylene chain, a polyol having a polyoxyalkylene chain, an epoxy resin having a polyoxyalkylene chain, and a phenolphthalein-type epoxy resin.

9. The sheet in accordance with claim 5,
wherein the curing agent contains a solid phenol novolak resin.

10. The sheet in accordance with claim 1,
wherein the sheet has a single-layer structure.

11. The sheet in accordance with claim 1,
wherein the sheet has an amount of warpage after curing of 12 mm or less, the amount of warpage after curing being determined by placing the sheet on a silicon wafer with a diameter ø of 12 inches and a thickness of 775 μm, and then subjecting the sheet to heat molding under the following condition:
molding pressure: 5 MPa,
molding temperature: 125 °C,
molding time: 10 minutes,
lowest vacuum degree: 200 Pa, and
post mold curing (post-curing): 150 °C/3 h or 180 °C/1.5 h.

12. A method for sealing an electronic component mounting substrate comprising the steps of:
(a) preparing the electronic component mounting substrate that includes a plurality of electronic components and a substrate, and also includes a space between the electronic components and the substrate;
(b) placing a mold underfill sealing sheet that is a thermosetting resin composition sheet on the electronic component mounting substrate so as to be in contact with the electronic components; and
(c) heat molding the placed sheet to fill the space between the electronic components and the substrate with a melted material of the sheet and curing the melted material,
wherein the heat molding is performed at a heating temperature of 110 °C or more and 175 °C or less, and
the sheet has a viscosity increasing rate of less than 9, the viscosity increasing rate being a ratio (V90/V0) of a viscosity V90 obtained 90 seconds after a start of measurement performed at a measurement temperature of 125 °C for a measurement time of 150 seconds relative to a viscosity V0 obtained 0 seconds after the start of measurement.

13. The method for sealing an electronic component mounting substrate in accordance with claim 12,
wherein, where a distance between an arbitrarily selected point P on a frame line that surrounds all of the plurality of electronic components while minimizing a surrounded area and a center of the substrate is represented by Lp,
a distance Lq between an intersecting point Q of a straight line that passes through the point P and the center of the substrate with an outer edge of the sheet and the center of the substrate is 0.9 Lp or more.

14. The method for sealing an electronic component mounting substrate in accordance with claim 12,
wherein the thermosetting resin composition contains a base resin, a curing agent, and a filler, and the maximum particle size of the filler is smaller than a height (H) of the space between the electronic components and the substrate and a minimum distance (W) between the electronic components.

15. A sealed body of an electronic component mounting substrate comprising:
the electronic component mounting substrate that includes a plurality of electronic components and a substrate, and also includes a space between the electronic components and the substrate; and
a cured material of a mold underfill sealing sheet that is a thermosetting resin composition sheet that undermold seals the space and overmold seals the electronic components,
wherein the sheet has a viscosity increasing rate of less than 9, the viscosity increasing rate being a ratio (V90/V0) of a viscosity V90 obtained 90 seconds after a start of measurement performed at a measurement temperature of 125 °C for a measurement time of 150 seconds relative to a viscosity V0 obtained 0 seconds after the start of measurement.
